(19) United States
(12) Patent Application Publication
(10) Pub. No.: US 2017/0287825 A1
(43) Pub. Date: Oct. 5, 2017

(54) FAN-OUT SEMICONDUCTOR PACKAGE AND METHOD OF MANUFACTURING SAME

(71) Applicant: SAMSUNG ELECTRO-MECHANICS CO., LTD., Suwon-si (KR)

(72) Inventors: Yong Koon LEE, Suwon-si (KR); Sang Kyu LEE, Suwon-si (KR); Yong Jin SEOL, Suwon-si (KR)

(21) Appl. No.: 15/352,060

(22) Filed: Nov. 15, 2016

(30) Foreign Application Priority Data
Mar. 31, 2016 (KR) 10-2016-0039326

(51) Int. Cl. H01L 23/498; H01L 23/29; H01L 23/31; H01L 21/56; H01L 23/00; H01L 23/367; H01L 21/48; H01L 23/552; H01L 23/538

(52) U.S. Cl. CPC H01L 23/49827; H01L 23/552; H01L 23/29; H01L 23/3128; H01L 23/49816; H01L 23/49838; H01L 23/5389; H01L 23/49811; H01L 24/02; H01L 23/367; H01L 21/486; H01L 21/4846; H01L 21/56; H01L 2224/02379; H01L 2224/02373

(57) ABSTRACT

A fan-out semiconductor package include a frame having a through hole; a semiconductor chip disposed in the through hole, and having an active surface, an inactive surface, and a side surface; an encapsulant disposed on one sides of the frame and the semiconductor chip, and in a space between the frame and the semiconductor chip in the through hole, a first conductive layer disposed on a sidewall of the through hole, a second conductive layer disposed on one side of the frame, and connected to the first conductive layer, a line via passing through the encapsulant, and connected to the second conductive layer, and a third conductive layer covering at least the inactive surface of the semiconductor chip on the encapsulant, and connected to the line via.

### CROSS-REFERENCE TO RELATED APPLICATION

This application claims the benefit of priority to Korean Patent Application No. 10-2016-0039326, filed on Mar. 31, 2016 with the Korean Intellectual Property Office, the entirety of which is incorporated herein by reference.

### TECHNICAL FIELD

The present disclosure relates to a fan-out semiconductor package and a method of manufacturing the same, such as a fan-out integrated circuit (IC) package and a method of manufacturing the same.

### BACKGROUND

A semiconductor package is a type of package technology for electrically connecting a semiconductor chip to a printed circuit board (PCB), such as the main board of an electronic device, or the like, and protecting the semiconductor chips from external impacts, and can be distinguished from other types of technology of embedding the semiconductor chip in a PCB, such as an interposer substrate. Meanwhile, one significant recent trend in the development of technology related to the semiconductor chip is to reduce the size of the semiconductor chip. Hence, in the field of packaging, in accordance with a rapid increase in demand for compact semiconductor chip, or the like, the implementation of a semiconductor package having a compact size and including a plurality of pins has been demanded.

One type of package technology suggested to satisfy the technical demand as described above is a wafer level package (WLP) using redistribution of an electrode pad included in a semiconductor chip formed on a wafer. WLPs include a fan-in WLP and a fan-out WLP. In particular, the fan-out WLP has a reduced size, and is advantageous in terms of implementing a plurality of pins. Therefore, the fan-out WLP has been actively developed.

Meanwhile, in the case of the WLP simply encapsulating an semiconductor chip with a common encapsulant material as described above, it is difficult to properly control a high level of electromagnetic waves and heat that may be generated when a fan-out semiconductor package has a high-level function or the like.

### SUMMARY

An aspect of the present disclosure may provide a fan-out semiconductor package that may effectively control electromagnetic waves and heat that may be generated by a semiconductor chip, and a method of efficiently manufacturing the same.

An aspect of the present disclosure may provide a frame having a conductive layer that may surround a side surface of a semiconductor chip in a region in which the semiconductor chip is encapsulated in a fan-out semiconductor package, provide a conductive layer that may cover an inactive surface of the semiconductor chip on an encapsulant, and connect the conductive layers by a line via passing through the encapsulant.

According to an aspect of the present disclosure, a fan-out semiconductor package includes: a frame having a through hole; a semiconductor chip disposed in the through hole, and having an active surface having an electrode pad, an inactive surface opposing the active surface, and a side surface connecting the active surface and the inactive surface; an encapsulant disposed on one sides of the frame and the semiconductor chip, and in a space between the frame and the semiconductor chip in the through hole; a first conductive layer disposed on a sidewall of the through hole; a second conductive layer disposed on one side of the frame, and connected to the first conductive layer; a line via passing through the encapsulant, and connected to the second conductive layer; and a third conductive layer covering at least the inactive surface of the semiconductor chip on the encapsulant, and connected to the line via.

According to an aspect of the present disclosure, a method of manufacturing a fan-out semiconductor package includes: manufacturing a frame having a through hole; forming a first conductive layer on a sidewall of the through hole, and forming a second conductive layer on one side of the frame to be connected to the first conductive layer; disposing, in the through hole, a semiconductor chip having an active surface having an electrode pad, an inactive surface opposing the active surface, and a side surface connecting the active surface and the inactive surface; forming an encapsulant on one sides of the frame and the semiconductor chip, and in a space between the frame and the semiconductor chip in the through hole; forming a line via passing through the encapsulant to be connected to the second conductive layer; and forming a third conductive layer on the encapsulant to be connected to the line via and cover at least the inactive surface of the semiconductor chip.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIG. 9 is a schematic cross-sectional view illustrating an example of a fan-out semiconductor package;

FIG. 10 is a schematic cross-sectional plan view taken along line I-I′ of FIG. 9;

FIG. 11 is a schematic flowchart illustrating an example of a process of manufacturing the fan-out semiconductor package of FIG. 9;

FIGS. 12A through 12C are schematic views illustrating an example of a process of forming a line via and a third conductive layer of the fan-out semiconductor package of FIG. 9;

FIG. 13 is a schematic cross-sectional view illustrating another example of a fan-out semiconductor package; and

FIG. 14 is a schematic cross-sectional plan view taken along line II-II′ of FIG. 13.

### DETAILED DESCRIPTION

Hereinafter, embodiments of the present disclosure will be described as follows with reference to the attached drawings.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no other elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship relative to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” relative to other elements would then be oriented “below,” or “lower” relative to the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present disclosure will be described with reference to schematic views illustrating embodiments of the present disclosure. In the drawings, for example, due to manufacturing techniques and/or tolerances, modifications of the shape shown may be estimated. Thus, embodiments of the present disclosure should not be construed as being limited to the particular shapes of regions shown herein, for example, to include a change in shape results in manufacturing. The following embodiments may also be constituted by one or a combination thereof.

The contents of the present disclosure described below may have a variety of configurations and propose only a required configuration herein, but are not limited thereto.

### Electronic Device

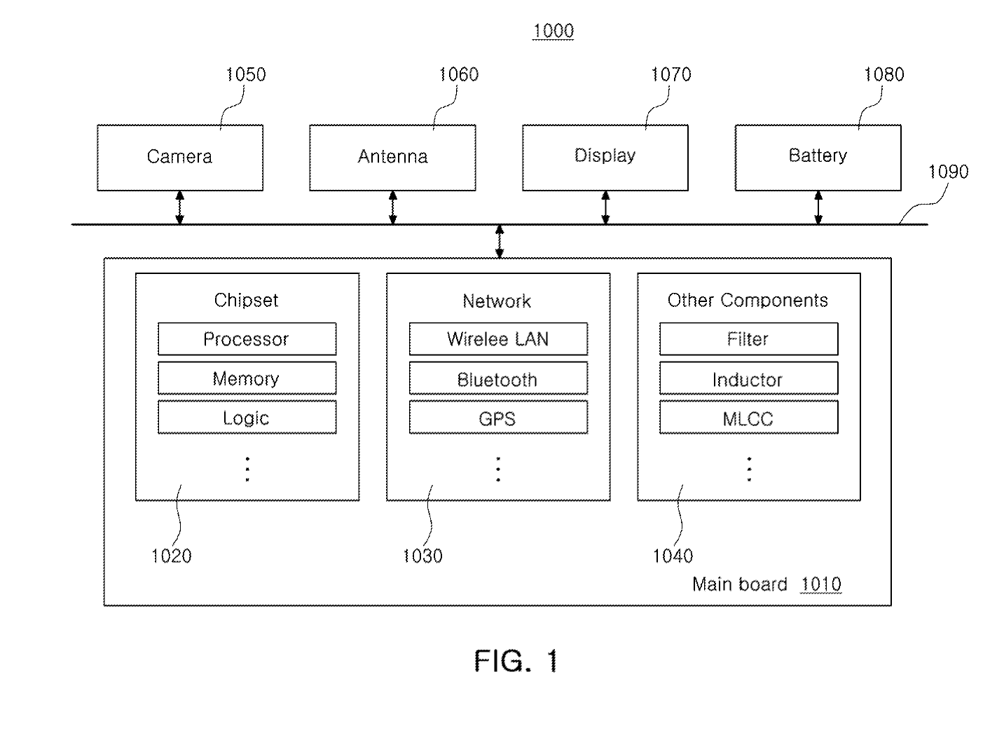

FIG. 1 is a schematic block diagram illustrating an example of an electronic device system.

Referring to FIG. 1, an electronic device 1000 may accommodate a mother board 1010. The mother board 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like, or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on type of the electronic device 1000, the electronic device 1000 may include other components that may or may not be physically or electrically connected to the mother board 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

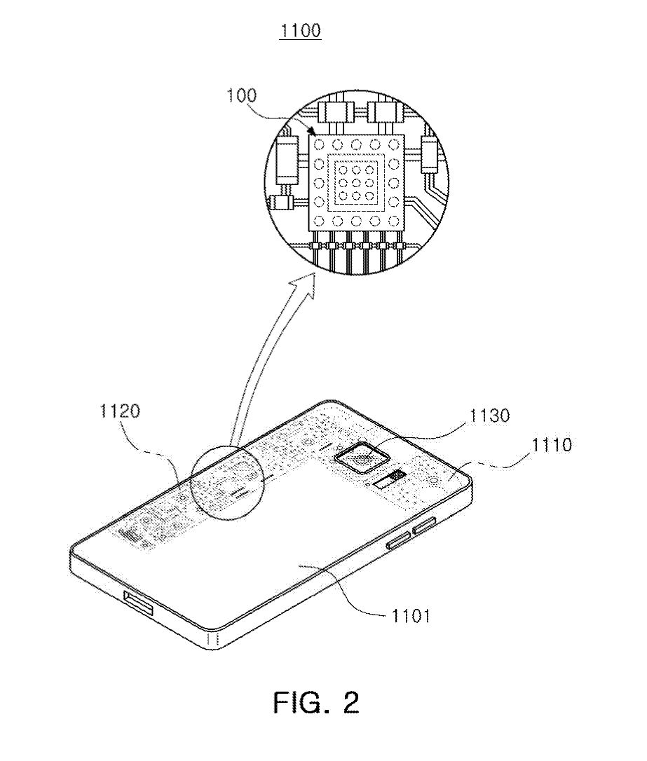

FIG. 2 is a schematic perspective view illustrating an example of an electronic device.

Referring to FIG. 2, a semiconductor package may be used for various purposes in the various electronic devices 1000 as described above. For example, a main board 1110 may be accommodated in a body 1101 of a smartphone 1100, and various electronic components 1120 may be physically or electrically connected to the main board 1110. In addition, other components that may or may not be physically or electrically connected to the main board 1110, such as the camera module 1050, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself is not used, but is packaged and is used in an electronic device, or the like, in a packaged state.

Here, semiconductor packaging is required due to the existence of a difference in a circuit width between the semiconductor chip and a main board of the electronic device in terms of electrical connections. In detail, connection pads of the semiconductor chip and an interval between the connection pads of the semiconductor chip are very fine, but a size of component mounting pads of the main board used in the electronic device and an interval between the component mounting pads of the main board are significantly larger than those of the semiconductor chip. Therefore, it may be difficult to directly mount the semiconductor chip on the main board, and a packaging technology for buffering a difference in a circuit width between the semiconductor chip and the main board is required.

A semiconductor package manufactured by the packaging technology may be divided into a fan-in semiconductor package and a fan-out semiconductor package depending on a structure and a purpose thereof.

The fan-in semiconductor package and the fan-out semiconductor package will hereinafter be described in more detail with reference to the drawings.

(Fan-In Semiconductor Package)

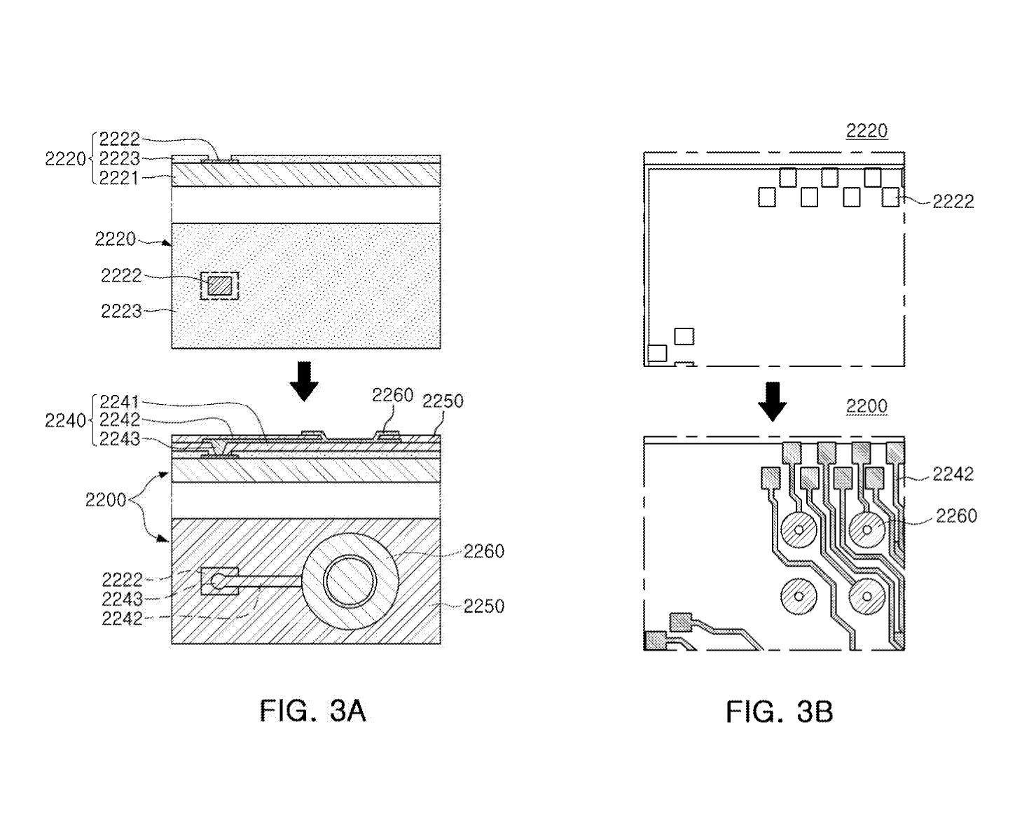

FIGS. 3A and 3B are schematic cross-sectional views illustrating states of a fan-in semiconductor package before and after being packaged.

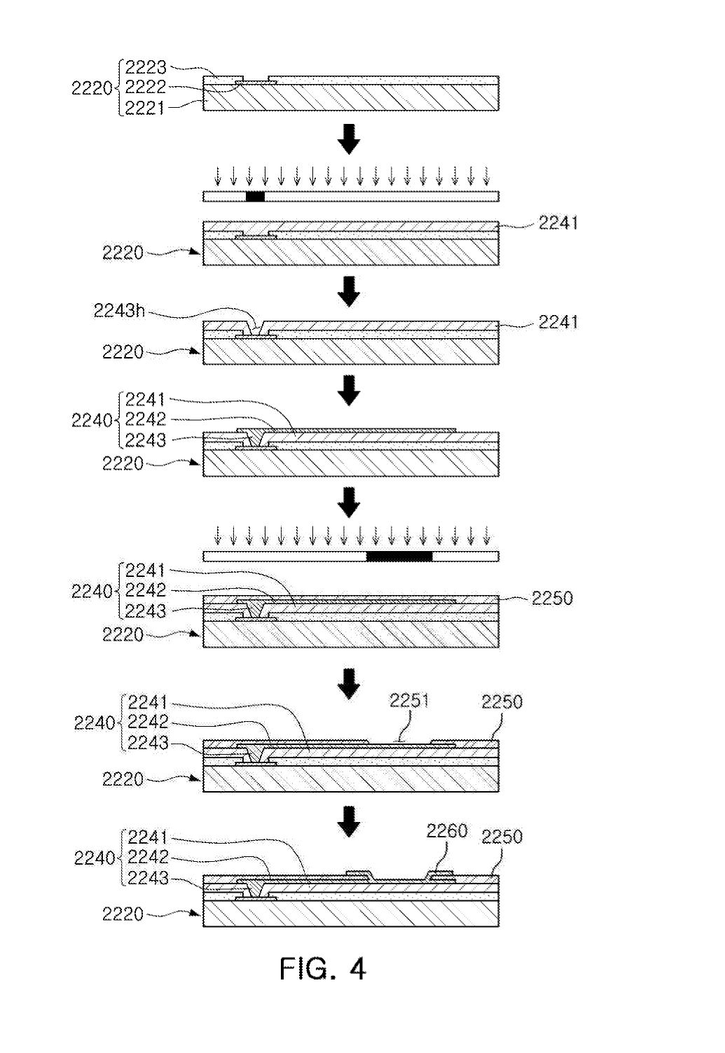

FIG. 4 is schematic cross-sectional views illustrating a packaging process of a fan-in semiconductor package.

Referring to the drawings, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. Here, since the connection pads 2222 are very small, it is difficult to mount the integrated circuit (IC) on an intermediate level printed circuit board (PCB) as well as on the main board of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in a smartphone have been manufactured in fan-in semiconductor package form. In detail, many elements mounted in the smartphone have been developed to implement a rapid signal transfer while having a compact size.

However, since all of the I/O terminals need to be disposed inside the semiconductor chip in the fan-in semiconductor package, the fan-in semiconductor package has a large spatial limitation. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the main board of the electronic device. The reason is that even though a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip are not enough to directly mount the fan-in semiconductor package on the main board of the electronic device.

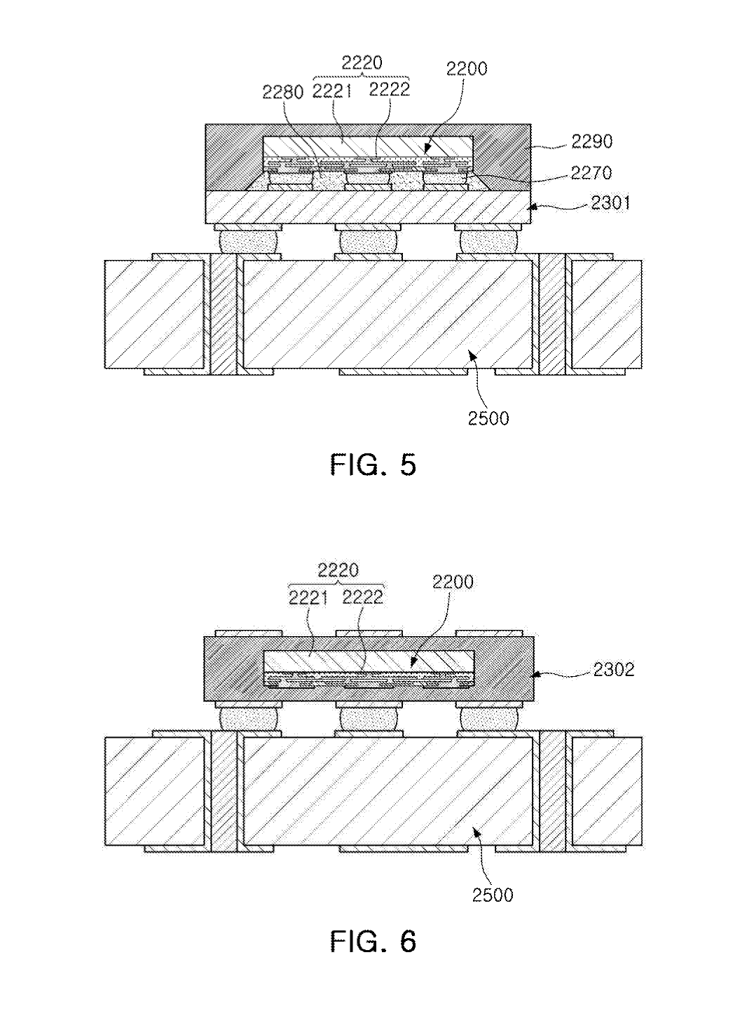

FIG. 5 is a schematic cross-sectional view illustrating a case in which a fan-in semiconductor package is mounted on an interposer substrate and is finally mounted on a main board of an electronic device.

FIG. 6 is a schematic cross-sectional view illustrating a case in which a fan-in semiconductor package is embedded in an interposer substrate and is finally mounted on a main board of an electronic device.

Referring to the drawings, in a fan-in semiconductor package 2200, connection pads 2222, that is, I/O terminals, of a semiconductor chip 2220 may be redistributed once more through an interposer substrate 2301, and the fan-in semiconductor package 2200 may be finally mounted on a main board 2500 of an electronic device in a state in which it is mounted on the interposer substrate 2301. Here, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed once more by the interposer substrate 2302 in a state in which the fan-in semiconductor package 2200 is embedded in the interposer substrate 2302, and the fan-in semiconductor package 2200 may be finally mounted on a main board 2500 of an electronic device.

As described above, it may be difficult to directly mount and use the fan-in semiconductor package on the main board of the electronic device. Therefore, the fan-in semiconductor package may be mounted on the separate interposer substrate and be then mounted on the main board of the electronic device through a packaging process or may be mounted and used on the main board of the electronic device in a state in which it is embedded in the interposer substrate.

(Fan-Out Semiconductor Package)

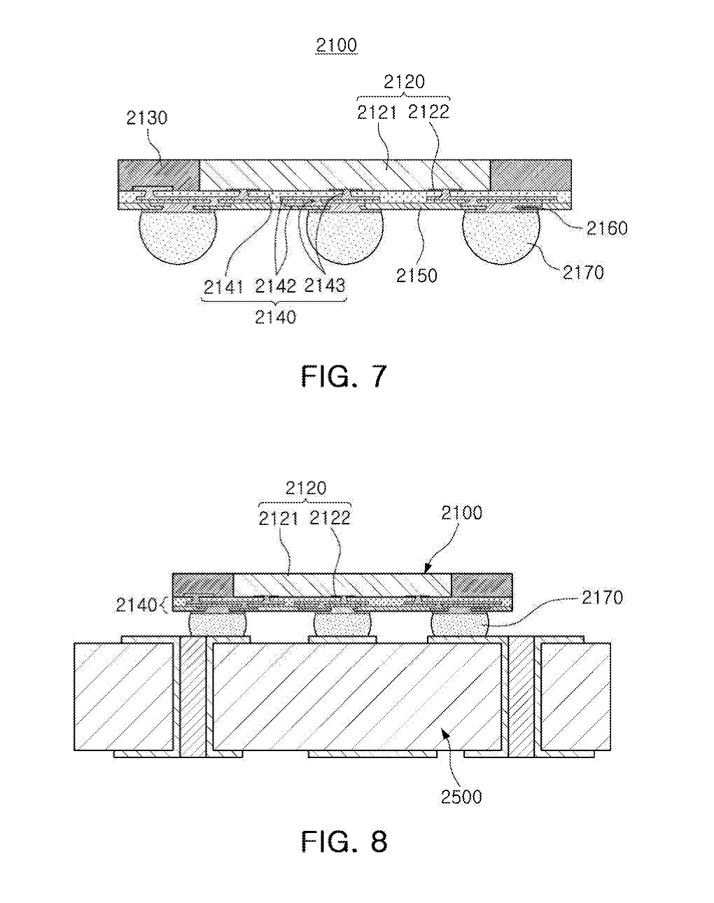

FIG. 7 is a schematic cross-sectional view illustrating a fan-out semiconductor package.

Referring to the drawing, in a fan-out semiconductor package 2100, for example, an outer side of a semiconductor chip 2120 may be protected by an encapsulant 2130, and connection pads 2122 of the semiconductor chip 2120 may be redistributed up to the outer side of the semiconductor chip 2120 by a connection member 2140. Here, a passivation layer 2150 may be further formed on the connection member 2140, and underbump metal layers 2160 may be further formed in openings of the passivation layer 2150. Solder balls 2170 may be further formed on the underbump metal layers 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed up outwardly of the semiconductor chip through the connection member formed on the semiconductor chip. As described above, in the fan-in semiconductor package, all of the I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed up to the outer side of the semiconductor chip through the connection member formed on the semiconductor chip as described above. Therefore, even though a size of the semiconductor chip is decreased, a standardized ball layout may be used in the fan-out semiconductor package as it is, such that the fan-out semiconductor package may be mounted on the main board of the electronic device without using a separate interposer substrate, as described below.

FIG. 8 is a schematic cross-sectional view illustrating a case in which a fan-out semiconductor package is mounted on a main board of an electronic device.

Referring to the drawing, a fan-out semiconductor package 2100 may be mounted on a main board 2500 of an electronic device through solder balls 2170, or the like. That is, as described above, the fan-out semiconductor package 2100 includes the connection member 2140 formed on the semiconductor chip 2120 and capable of redistributing the connection pads 2122 up to a fan-out region that is out of a size of the semiconductor chip 2120, such that the standardized ball layout may be used in the fan-out semiconductor package 2100 as it is. As a result, the fan-out semiconductor package 2100 may be mounted on the main board 2500 of the electronic device without using a separate interposer substrate, or the like.

As described above, since the fan-out semiconductor package may be mounted on the main board of the electronic device without using the separate interposer substrate, the fan-out semiconductor package may be implemented at a thickness less than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to occurrence of a warpage phenomenon.

Meanwhile, the fan-out semiconductor package refers to a package technology for mounting the semiconductor chip on the main board of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

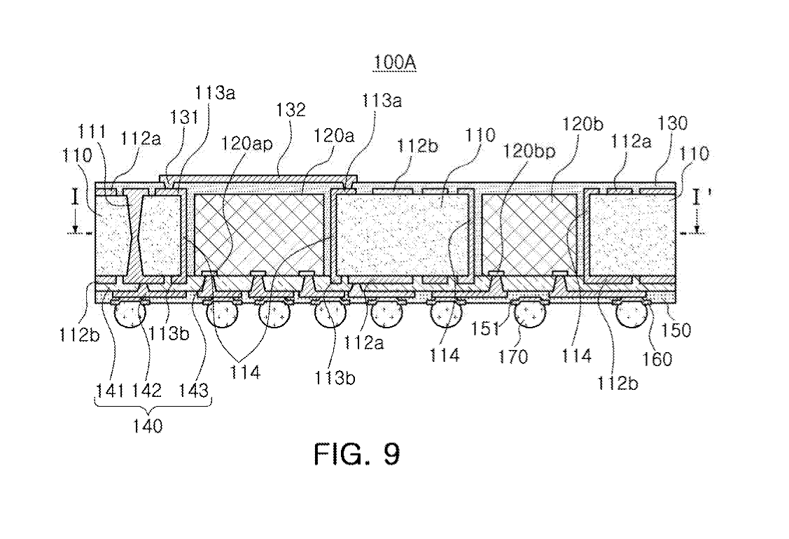

FIG. 9 is a schematic cross-sectional view illustrating an example of a fan-out semiconductor package.

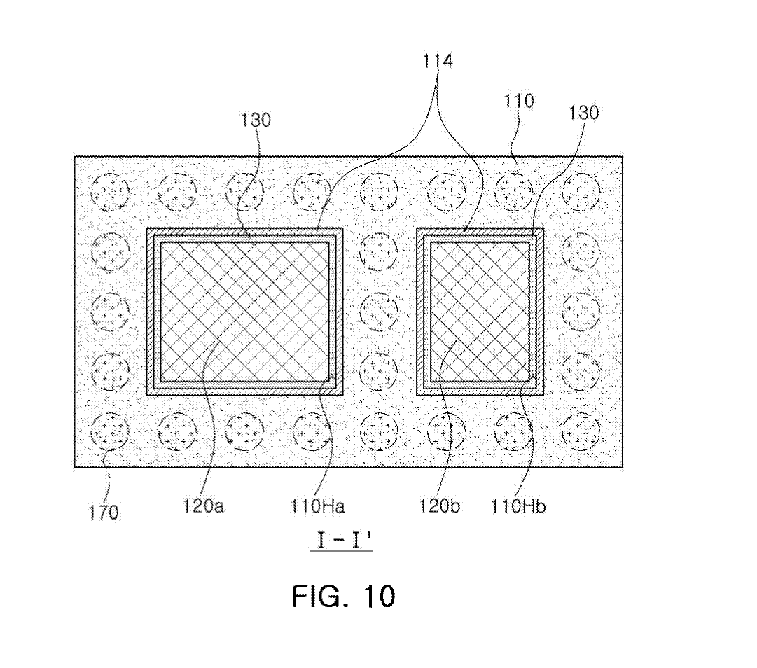

FIG. 10 is a schematic cross-sectional plan view taken along line I-I′ of FIG. 9.

Referring to FIGS. 9 and 10, a fan-out semiconductor package 100A according to an exemplary embodiment includes a frame 110 having a plurality of through holes 110Ha and 110Hb, a plurality of electronic components 120a and 120b disposed in the through holes 110Ha and 110Hb, respectively, each having an active surface having electrode pads 120ap and 120bp, an inactive surface opposing the active surface, and a side surface connecting the active surface and the inactive surface, and an encapsulant 130 disposed on one sides of the frame 110 and the electronic components 120a and 120b, and in a space between the frame 110 and the electronic components 120a and 120b in the through holes 110Ha and 110Hb.

A first conductive layer 114 is disposed on a sidewall of the through holes 110Ha and 110Hb. In addition, a second conductive layer 113a connected to the first conductive layer 114 is further disposed on one side of the frame 110 surrounding the electronic component 120a. In addition, a line via 131 passing through the encapsulant 130 and connected to the second conductive layer 113a is further disposed in the encapsulant 130 covering the electronic component 120a. In addition, a third conductive layer 132 covering at least the inactive surface of the electronic component 120a and connected to the line via 131 is further disposed on the encapsulant 130.

A general fan-out semiconductor package has adopted a structure in which the periphery of an electronic component is encapsulated by an encapsulant, such as an epoxy molding compound (EMC), to be surrounded thereby. In this case, electromagnetic interference (EMI) that may be generated by an electronic component, or caused by electromagnetic waves emanating from an external source, may cause operating characteristics of an electronic device, on which the electronic component is mounted, or the like, to be degraded. In addition, heat generated by a certain electronic component flows downwardly along a wiring layer, and only a very reduced amount of heat is conducted to an encapsulant having low thermal conductivity, thus reducing heat dissipation characteristics.

Meanwhile, the line via 131 and the third conductive layer 132 are selectively provided only around the electronic component 120a in which electromagnetic waves and heat are excessively generated as in the fan-out semiconductor package 100A according to an exemplary embodiment. When an inactive surface and a side surface of the electronic component 120a are entirely surrounded by conductive materials, electromagnetic waves generated by the electronic component 120a may be effectively prevented from interfering with the electronic component 120b, and heat generated by the electronic component 120a may be effectively distributed externally from the fan-out semiconductor package 100A. The electronic component 120b may also be surrounded by a conductive material by providing the line via 131 and the third conductive layer 132, if necessary, as in the electronic component 120a.

The respective components of the fan-out semiconductor package 100A according to an exemplary embodiment will hereinafter be described in more detail.

The frame 110 supports the fan-out semiconductor package 100A, and allows rigidity of the fan-out semiconductor package 100A to be maintained and uniformity of a thickness of the fan-out semiconductor package 100A to be secured. The frame 110 has the through holes 110Ha and 110Hb formed therein, and the through holes 110Ha and 110Hb have the electronic components 120a and 120b disposed therein, respectively. Unlike as illustrated in FIGS. 9 and 10, a greater number of through holes may be formed, and in this case, a greater number of electronic components may also be disposed. In addition, a plurality of electronic components may be disposed in a single through hole. In addition, the frame 110 may include a plurality of layers, and in this case, a wiring may be formed in a space between the layers.

A material of the frame 110 is not particularly limited as long as the material may support the fan-out semiconductor package 100A. For example, an insulating material is used. The insulating material may be a thermosetting resin such as an epoxy resin, a thermoplastic resin such as a polyimid, or a resin, impregnated with a stiffener such as a glass fiber or an inorganic filler, such as a prepreg (PPG), an Ajinomoto build-up film (ABF), an FR-4 resin, a bismaleimide triazine (BT) resin, or the like. Alternatively, a metal having excellent rigidity and thermal conductivity may be used. The metal may be an Fe—Ni-based alloy. A copper (Cu) plating layer is also formed on a surface of the Fe—Ni-based alloy to secure adhesive strength between the Fe—Ni-based alloy, and a molding material or an interlayer insulating material. In addition, glass, ceramic, plastic, or the like, may also be used.

If necessary, wiring patterns 112a and 112b are also disposed on one side and the other side of the frame 110. The wiring patterns 112a and 112b serve as redistribution lines for the electronic components 120a and 120b. A material of each of the wiring patterns 112a and 112b may be a conductive material such as copper (Cu), aluminum (Al), silver (Ag), tin (Sn), gold (Au), nickel (Ni), lead (Pb), titanium (Ti), or alloys thereof. The wiring patterns 112a and 112b perform various functions depending on designs of layers thereof. For example, each of the wiring patterns 112a and 112b serves as a ground (GND) pattern, a power (PWR) pattern, a signal (S) pattern, or the like. In this example, the S pattern includes various signals except for a GND pattern, a PWR pattern, or the like, for example, data signals, or the like. In addition, each of the wiring patterns 112a and 112b may serve as a via pad, a connection terminal pad, or the like. The wiring patterns 112a and 112b are connected by a via 111 passing through the frame 110. A material of the via 111, or the like, is the same as described above. The number of vias 111, or the like, is not particularly limited. Meanwhile, in FIG. 10, the illustration of the via 111 is omitted to illustrate a fan-out shape of a connection terminal 170.

Each of the electronic components 120a and 120b may be a dynamic component (for example, a diode, a vacuum tube, a transistor, or the like), or a passive component (for example, an inductor, a condenser, a resistor, or the like). Alternatively, each of the electronic components 120a and 120b may be an integrated circuit (IC) provided in an amount of several hundreds to several millions of elements or more integrated in a single chip. In other words, each of the electronic components 120a and 120b may be a semiconductor chip. If necessary, each of the electronic components 120a and 120b may also have an IC packaged in a flip chip form. The IC may be, for example, an application processor chip such as a central processor (for example, a CPU), a graphic processor (for example, a GPU), a digital signal processor, a cryptographic processor, a microprocessor, a microcontroller, or the like, but is not limited thereto.

The electronic components 120a and 120b have the electrode pads 120ap and 120bp, electrically connected to a redistribution layer 140, respectively and independently. The electrode pads 120ap and 120bp electrically connect the electronic components 120a and 120b to an external power source, and are formed of a conductive material without particular limitation. The conductive material may be copper (Cu), aluminum (Al), silver (Ag), tin (Sn), gold (Au), nickel (Ni), lead (Pb), titanium (Ti), or alloys thereof, but is not limited thereto. The electrode pads 120ap and 120bp are redistributed by the redistribution layer 140. The electrode pads 120ap and 120bp are embedded or protrude. A surface on which the electrode pads 120ap and 120bp are formed is an active layer, and a surface opposing the surface is an inactive surface. These surfaces are connected to the side surface.

When the electronic components 120a and 120b are ICs, the electronic components 120a and 120b have bodies, passivation layers, and electrode pads, respectively. The body is formed on the basis of, for example, an active wafer. Abase material of the body may be silicon (Si), germanium (Ge), gallium arsenide (GaAs), or the like. The passivation layer serves to externally protect the body, and is formed of, for example, an oxide layer or a nitride layer, or also formed of a double layer of an oxide layer and a nitride layer. The electrode pads 120ap and 120bp are the same as described above.

The encapsulant 130 protects the electronic components 120a and 120b. For this purpose, the encapsulant 130 encapsulates the electronic components 120a and 120b. A type of encapsulation is not particularly limited as long as at least portions of the electronic components 120a and 120b are surrounded by the encapsulant 130. In an example, the encapsulant 130 covers the one sides of the frame 110 and the electronic components 120a and 120b. In addition, the encapsulant 130 fills the space between the frame 110 and the electronic components 120a and 120b. In this example, the covering refers to the case in which a component is located in its corresponding direction, but does not directly contact a reference component, as well as to the case in which the component directly contacts the reference component. Meanwhile, the encapsulant 130 fills spaces of the through holes 110Ha and 110Hb to thus serve as an adhesive and reduce buckling of the electronic components 120a and 120b depending on a material of the encapsulant 130.

The material of the encapsulant 130 is not particularly limited. For example, the material may be an insulating material. The insulating material may be a thermosetting resin such as an epoxy resin, a thermoplastic resin such as a polyimid, or a resin, in which the thermosetting resin and the thermoplastic resin are impregnated with a stiffener such as an inorganic filler, such as an ABF. In addition, a known molding material, such as an EMC, may also be used. If necessary, the encapsulant 130 may include conductive particles to block electromagnetic waves.

The first conductive layer 114 blocks electromagnetic waves that may be generated from the side surface of the electronic component 120a and that of the electronic component 120b, and emits heat toward the frame 110. The first conductive layer 114 is continuously disposed on the sidewall of the through holes 110Ha and 110Hb to surround the side surfaces of the electronic components 120a and 120b. In this case, the side surfaces of the electronic components 120a and 120b are entirely surrounded by conductive materials, which may be formed on the entire sidewall of the through holes 110Ha and 110Hb, thus further improving electromagnetic wave shielding and heat dissipating effects. A material of the first conductive layer 114 may be a conductive material such as copper (Cu), aluminum (Al), silver (Ag), tin (Sn), gold (Au), nickel (Ni), lead (Pb), titanium (Ti), or alloys thereof.

The second conductive layer 113a connects the line via 131 to be described below to the abovementioned first conductive layer 114. The second conductive layer 113a is also continuously disposed on the one side of the frame 110 to be continuously connected to the first conductive layer 114. That is, the second conductive layer 113a and the first conductive layer 114 may meet each other at the entire edge of one end of the through hole 110Ha. In this case, the side surface and the inactive surface of the electronic component 120a are entirely surrounded by conductive materials, thus further improving electromagnetic wave shielding and heat dissipating effects. A material of the first conductive layer 114 may also be the abovementioned conductive material such as copper (Cu), aluminum (Al), silver (Ag), tin (Sn), gold (Au), nickel (Ni), lead (Pb), titanium (Ti), or alloys thereof. Similarly, a fourth conductive layer 113b connected to the first conductive layer 114 disposed on the sidewall of the through holes 110Ha is further disposed on the other side of the frame 110 surrounding the electronic component 120a, but is not limited thereto.

Resultantly, the line via 131 connects the abovementioned first conductive layer 114 to the third conductive layer 132 to be described below. The line via 131, which may have a closed loop to separate the encapsulant 130 into two discrete portions, continuously passes through the encapsulant 130 to continuously connect the second conductive layer 113a to the third conductive layer 132. In this case, the side surface and the inactive surface of the electronic component 120a are entirely surrounded by conductive materials, thus further improving electromagnetic wave shielding and heat dissipating effects. A material of the line via 131 may also be the abovementioned conductive material such as copper (Cu), aluminum (Al), silver (Ag), tin (Sn), gold (Au), nickel (Ni), lead (Pb), titanium (Ti), or alloys thereof.

The third conductive layer 132 blocks electromagnetic waves that may be generated from the inactive surface of the electronic component 120a, and emits heat externally. The third conductive layer 132 is coated on the encapsulant 130 in plate form. In this case, the inactive surface of the electronic component 120a is entirely covered to thus further improve electromagnetic wave shielding and heat dissipating effects. A material of the third conductive layer 132 may also be the abovementioned conductive material such as copper (Cu), aluminum (Al), silver (Ag), tin (Sn), gold (Au), nickel (Ni), lead (Pb), titanium (Ti), or alloys thereof.

The fan-out semiconductor package 100A according to an exemplary embodiment further includes the redistribution layer 140 disposed on the other sides of the frame 110 and the electronic components 120a and 120b, and electrically connected to the electronic components 120a and 120b. The redistribution layer 140 redistributes the electrode pads 120ap and 120bp of the electronic components 120a and 120b. Several tens to several hundreds of electrode pads 120ap and 120bp having various functions are redistributed by the redistribution layer 140, and are physically or electrically connected to an external power source by the connection terminal 170 to be described below depending on the functions. The redistribution layer 140 includes an insulating layer 141, a wiring pattern 142 disposed on the insulating layer 141, and a via 143 connecting the wiring pattern 142 passing through the insulating layer 141. In the fan-out semiconductor package 100A according to an exemplary embodiment, the redistribution layer 140 includes the wiring pattern 142 having a single layer, but is not limited thereto, and may also include a plurality of layers.

A material of the insulating layer 141 may be an insulating material. The insulating material may be a photosensitive insulating material such as a photoimageable dielectric (PID) resin in addition to the abovementioned insulating material. In this case, the insulating layer 141 is formed to have a further reduced thickness, and a fine pitch of the via 143 may be achieved more easily. When the insulating layer 141 includes a plurality of layers, materials of the layers may be the same as each other, and may also be different from each other, if necessary. In addition, when the insulating layer 141 includes a plurality of layers, the layers may be integrated depending on processes, and boundaries therebetween may thus not be readily apparent.

The wiring pattern 142 substantially serves as a redistribution line. A material of the wiring pattern 142 may be a conductive material such as copper (Cu), aluminum (Al), silver (Ag), tin (Sn), gold (Au), nickel (Ni), lead (Pb), titanium (Ti), or alloys thereof. The wiring pattern 142 performs various functions depending on a design of a layer thereof. For example, the wiring pattern 142 serves as a GND pattern, a PWR pattern, an S pattern, or the like. In this example, the S pattern includes various signals except for a GND pattern, a PWR pattern, or the like, for example, data signals, or the like. In addition, the wiring pattern 142 serves as a via pad, a connection terminal pad, or the like.

The via 143 electrically connects the wiring pattern 142, the electrode pads 120ap and 120bp, or the like, formed in different layers, resulting in forming an electrical path in the fan-out semiconductor package 100A. A material of the via 143 may also be a conductive material such as copper (Cu), aluminum (Al), silver (Ag), tin (Sn), gold (Au), nickel (Ni), lead (Pb), titanium (Ti), or alloys thereof. The via 143 is fully filled with the conductive material, or the conductive material is also formed along a wall of the via 143. In addition, the via 143 may have all shapes known in the related art, such as a tapered shape, a cylindrical shape, and the like.

The fan-out semiconductor package 100A according to an exemplary embodiment further includes a passivation layer 150 disposed on the redistribution layer 140. The passivation layer 150 protects the redistribution layer 140 from external physical or chemical damage. The passivation layer 150 has an opening 151 exposing at least a portion of the wiring pattern 142 of the redistribution layer 140. The opening 151 may expose the entirety of or only a portion of a surface of the wiring pattern 142, and in some cases, may also expose a side surface thereof.

A material of the passivation layer 150 is not particularly limited, and may be, for example, a solder resist. Alternatively, a material similar to that of the insulating layer 141 of the redistribution layer 140, for example, a PID resin, may also be used. Alternatively, a material similar to the encapsulant 130, for example, an ABF, may also be used. The passivation layer 150 generally includes a single layer, but may also include multiple layers, if necessary.

The fan-out semiconductor package 100A according to an exemplary embodiment further includes an under-bump metal layer 160 disposed on a wall surface of the opening 151 of the passivation layer 150 and on the exposed wiring pattern 142 of the redistribution layer 140. The under-bump metal layer 160 may increase connection reliability of the connection terminal 170 to be described below, resulting in an improvement in board level reliability of the fan-out semiconductor package 100A. The under-bump metal layer 160 is formed by a known metallization method using a known conductive material, for example, a metal.

The fan-out semiconductor package 100A according to an exemplary embodiment further includes the connection terminal 170 disposed on the under-bump metal layer 160. The connection terminal 170 physically or electrically connects the fan-out semiconductor package 100A to an external power source. For example, the fan-out semiconductor package 100A is mounted on a main board of an electronic device by the connection terminal 170. The number, an interval, a disposition, or the like, of connection terminals 170 is not particularly limited, and may be sufficiently modified by a person skilled in the art depending on design particulars. For example, the connection terminal 170 may be provided in an amount of several tens to several thousands, according to the number of electrode pads 120ap and 120bp of the electronic components 120a and 120b, but is not limited thereto, and may also be provided in an amount greater than or equal to or less than or equal to several tens to several thousands.

The connection terminal 170 is formed of a conductive material such as copper (Cu), aluminum (Al), silver (Ag), tin (Sn), gold (Au), nickel (Ni), lead (Pb), titanium (Ti), a solder, or the like. However, the conductive material is only an example, and the present disclosure is not limited thereto. The connection terminal 170 may be a land, a ball, a pin, or the like. The connection terminal 170 may include a single layer or multiple layers. When the connection terminal 170 includes multiple layers, the connection terminal 170 includes a copper pillar and a solder. When the connection terminal 170 includes a single layer, the connection terminal 170 includes a tin-silver solder or copper. However, the connection terminal 170 is only an example, and the present disclosure is not limited thereto.

At least one connection terminal 170 is disposed in a fan-out region. The fan-out region defines a region outside of a region in which an electronic component is disposed. For example, the fan-out semiconductor package 100A according to an exemplary embodiment is a fan-out package. The fan-out package may have excellent reliability as compared to a fan-in package, may allow a plurality of input/output (I/O) terminals to be implemented, and may facilitate a 3D interconnection. In addition, as compared to a ball grid array (BGA) package, a land grid array (LGA) package, or the like, the fan-out package may be mounted on an electronic device without a separate board. Thus, the fan-out package may be manufactured to have a reduced thickness, and may have excellent price competitiveness.

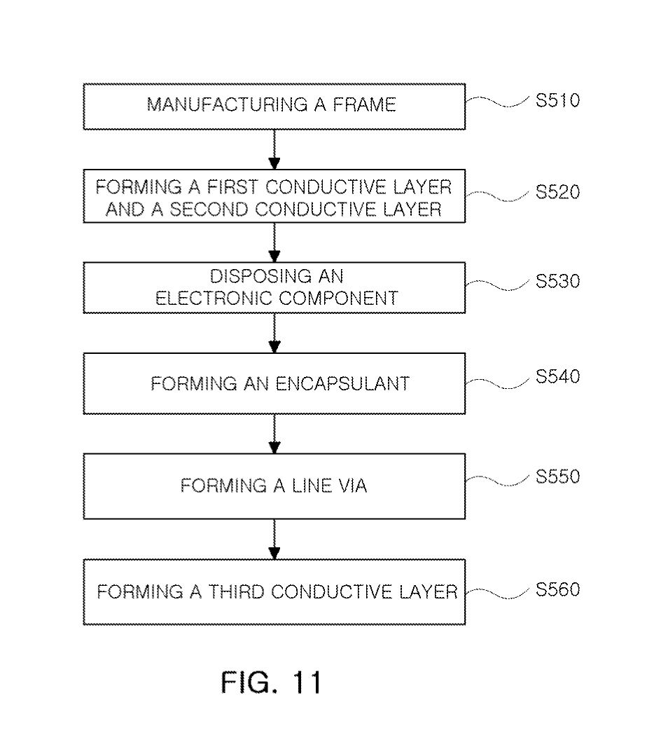

FIG. 11 is a schematic flow chart illustrating an example of a process of manufacturing the fan-out semiconductor package of FIG. 9.

Referring to FIG. 11, a method of manufacturing the fan-out semiconductor package 100A according to an exemplary embodiment includes manufacturing the frame 110 (S510), forming the first and second conductive layers 114 and 113a (S520), disposing the electronic components 120a and 120b (S530), forming the encapsulant 130 (S540), forming the line via 131 (S550), and forming the third conductive layer 132 (S560).

In more detail, the method includes manufacturing the frame 110 having the through holes 110Ha and 110Hb (S510), forming the first conductive layer 114 on the sidewall of each of the through holes 110Ha and 110Hb and forming the second conductive layer 113a on the one side of the frame 110 to be connected to the first conductive layer 114 (S520), disposing the electronic components 120a and 120b each having the active surface having the electrode pads 120ap and 120bp, the inactive surface opposing the active surface, and the side surface connecting the active surface and the inactive surface in the through holes 110Ha and 110Hb, respectively (S530), forming the encapsulant 130 on the one sides of the frame 110 and the electronic components 120a and 120b and in the space between the frame 110 and the electronic components 120a and 120b in the through holes 110Ha and 110Hb (S540), forming the line via 131 passing through the encapsulant 130 around the electronic component 120a to be connected to the second conductive layer 113a (S550), and forming the third conductive layer 132 on the encapsulant 130 to cover at least the inactive surface of the electronic component 120a (S560).

The through holes 110Ha and 110Hb are formed using mechanical drilling or laser drilling. The through holes 110Ha and 110Hb are not limited thereto, and are also formed by a sand blasting method using particles for grinding, a dry etching method using plasma, or the like. When the through holes 110Ha and 110Hb are formed using mechanical drilling or laser drilling, the through holes 110Ha and 110Hb are subject to a desmearing treatment, such as a permanganate method, to remove resin smearing in the through holes 110Ha and 110Hb. When the through holes 110Ha and 110Hb are formed, a hole for the via 111 may further be formed.

The first and second conductive layers 114 and 113a may be formed by a plating process. The plating process may be electrolytic copper plating or electroless copper plating. In more detail, the first and second conductive layers 114 and 113a are formed by a method such as a chemical vapor deposition (CVD) process, a physical vapor deposition (PVD) process, a sputtering process, a subtractive process, an additive process, a semi-additive process (SAP), or a modified semi-additive process (MSAP), but are not limited thereto. When the first and second conductive layers 114 and 113a are formed, the wiring patterns 112a and 112b, the fourth conductive layer 113b, the via 111, or the like, may also further be formed by the plating process.

The electronic components 120a and 120b are disposed by a method of bonding a bonding film or the like to the other side of the frame 110 and then bonding the electronic components 120a and 120b to the bonding film exposed in the through holes 110Ha and 110Hb. Any bonding film may be used as long as the bonding film may secure the frame 110 or the like, and a known tape or the like may be used as an unlimited example. The known tape may be, for example, a thermally treated thermosetting adhesive tape of which adhesive strength is reduced by a thermal treatment, or an ultraviolet thermosetting adhesive tape of which adhesive strength is decreased by ultraviolet irradiation. The electronic components 120a and 120b are disposed in a face-down form such that the electrode pads 120ap and 120bp are bonded to the bonding film.

The encapsulant 130 is formed by a known method, for example, by laminating and curing an encapsulant 130 precursor. Alternatively, the encapsulant 130 is also formed by applying and curing a material of the encapsulant 130 such that the electronic components 120a and 120b are encapsulated on the bonding film. The curing allows the electronic components 120a and 120b to be secured. A laminating method may include, for example, a method of hot pressing a precursor, cooling the hot pressed precursor by a cold press, and separating a tool from the cooled precursor, or the like, the hot pressing including pressurizing the precursor at high temperatures for a certain period of time, depressurizing the pressurized precursor, and cooling the depressurized precursor to room temperature. An application method may include, for example, a screen printing method of applying ink with a squeegee, a spray printing method of misting and applying ink, or the like, but is not limited thereto.

A method of forming the line via 131 and the third conductive layer 132 will be described below.

If necessary, the redistribution layer 140 is further formed, and formed by a method of disposing the electronic components 120a and 120b, delaminating the bonding film, forming the insulating layer 141 in a region from which the bonding film is delaminated, and forming the wiring pattern 142 and the via 143 in the insulating layer 141. The insulating layer 141 is formed by the abovementioned lamination or application method, the wiring pattern 142 is formed by the abovementioned plating process, and the via 143 is formed by a method of forming a hole by a photolithography method, mechanical drilling, or laser drilling, depending on a material of the insulating layer 141 and filling the hole with a plating material, or the like. However, the present disclosure is not limited thereto.

If necessary, the passivation layer 150 is formed on the redistribution layer 140. Similarly, the passivation layer 150 is formed by a method of laminating and curing a passivation layer 150 precursor, a method of applying and curing a material of the passivation layer 150, or the like. The opening 151 is formed in the passivation layer 150 such that at least a portion of the wiring pattern 142 of the redistribution layer 140 is exposed, and the under-bump metal layer 160 is also formed on the opening 151 by the known metallization method.

If necessary, the connection terminal 170 is formed on the under-bump metal layer 160. A method of forming the connection terminal 170 is not particularly limited, and the connection terminal 170 is formed by a method well known in the related art according to a structure or shape of the connection terminal 170. The connection terminal 170 is secured by reflow, a portion of the connection terminal 170 is embedded in the passivation layer 150, and the remainder of the connection terminal 170 is externally exposed to strengthen securing force, thus increasing reliability. In some cases, the connection terminal 170 is also formed to the under-bump metal layer 160, and thereafter, a customer company may form a connection terminal by a separate subsequent process, if necessary.

Meanwhile, a series of processes may include manufacturing a large-sized frame 110 to facilitate mass production, manufacturing a plurality of fan-out semiconductor packages 100A by the abovementioned processes, and then sigulating the fan-out semiconductor packages 100A by a sawing process. In this case, productivity may be increased.

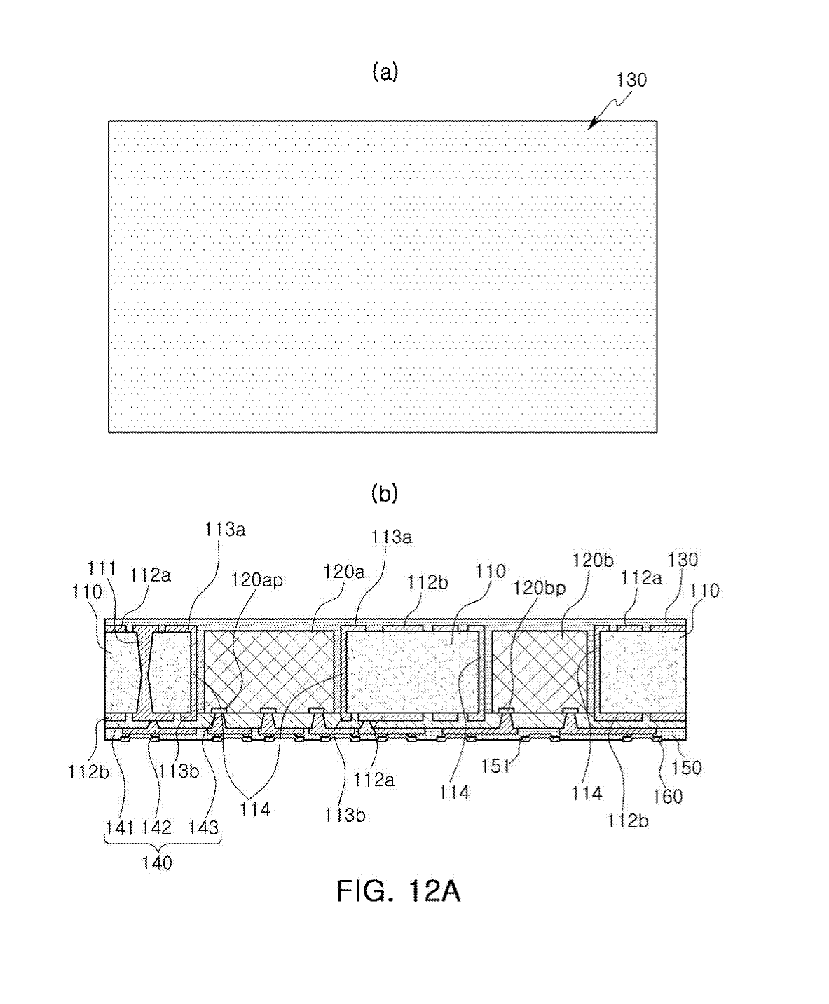

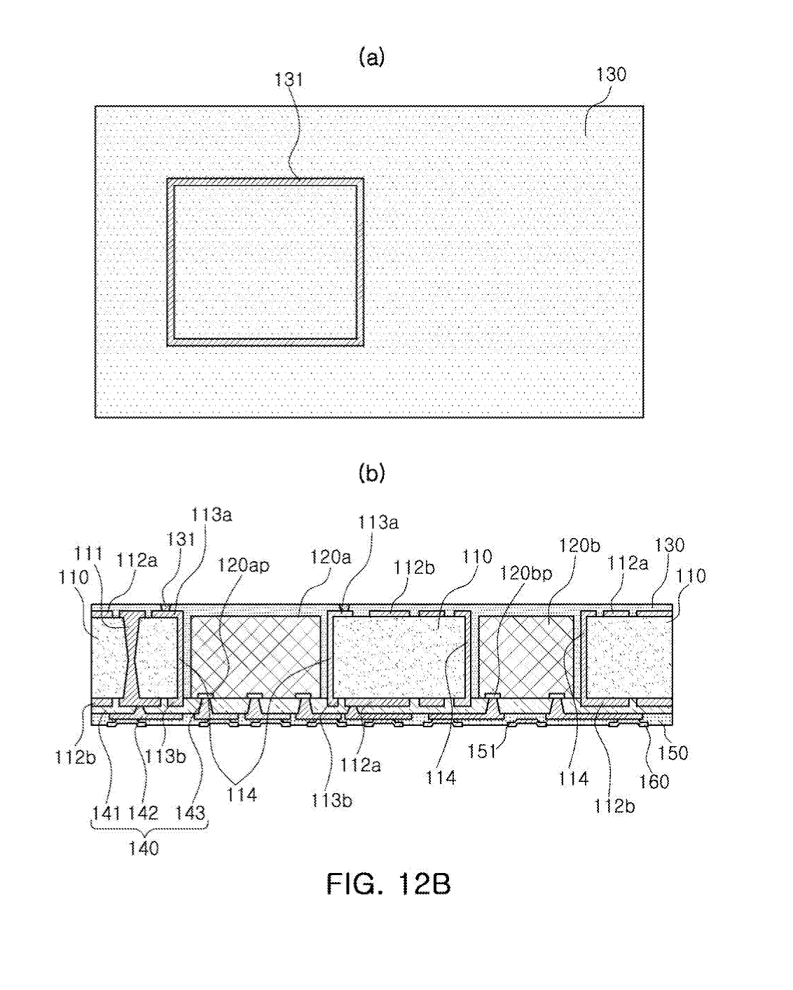

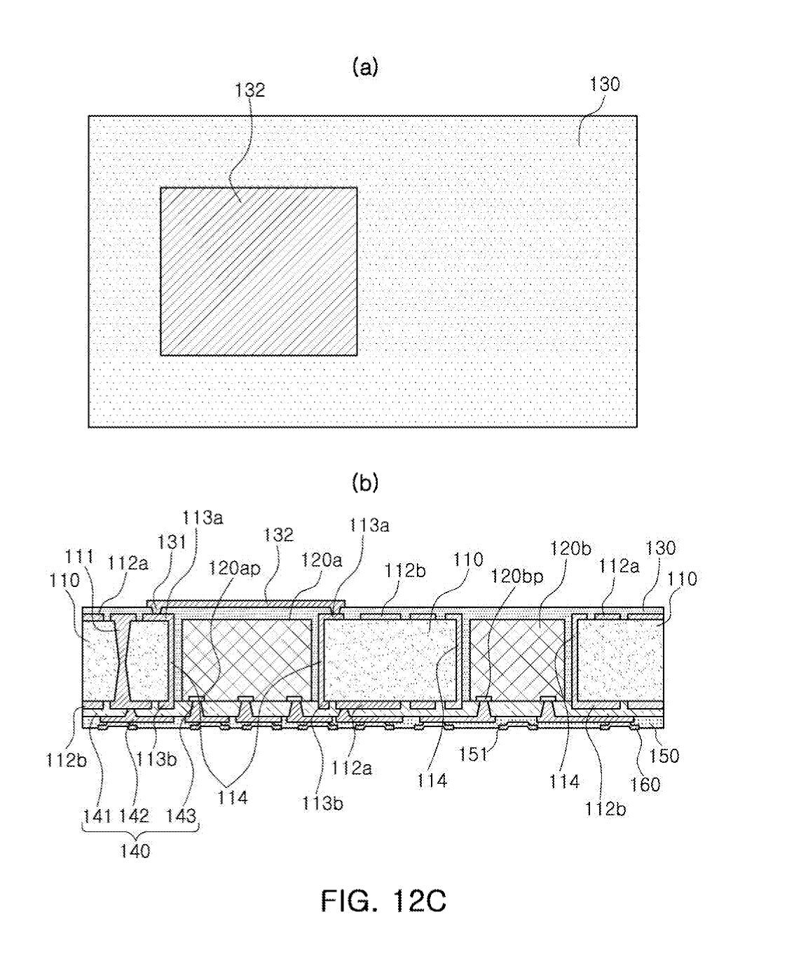

FIGS. 12A through 12C are schematic views illustrating an example of a process of forming a line via and a third conductive layer of the fan-out semiconductor package of FIG. 9.

Referring to FIG. 12A, the fan-out semiconductor package 100A manufactured by the abovementioned series of processes is prepared. Meanwhile, in the abovementioned series of processes, the processes do not necessarily need to be performed in the order described above, unless particularly mentioned. If necessary, the processes may also be performed simultaneously or in a different order from the order described above.

Referring to FIG. 12B, the line via 131 is selectively formed only around the electronic component 120a of the electronic components 120a and 120b. The line via 131, which may have a closed loop to separate the encapsulant 130 into two discrete portions, is continuously connected to the second conductive layer 113a, and formed by forming a line via hole continuously passing through the encapsulant 130 by the abovementioned method and filling the formed line via hole with a conductive material using the abovementioned plating process or the like. If necessary, the line via 131 is also formed around the electronic component 120b.

Referring to FIG. 12C, the third conductive layer 132 is selectively formed only around the electronic component 120a of the electronic components 120a and 120b. The third conductive layer 132 is continuously connected to the line via 131, and formed to have a type of plate on the encapsulant 130 to cover the inactive surface of the electronic component 120a. A formation method may be the abovementioned plating process or the like, but is not limited thereto.

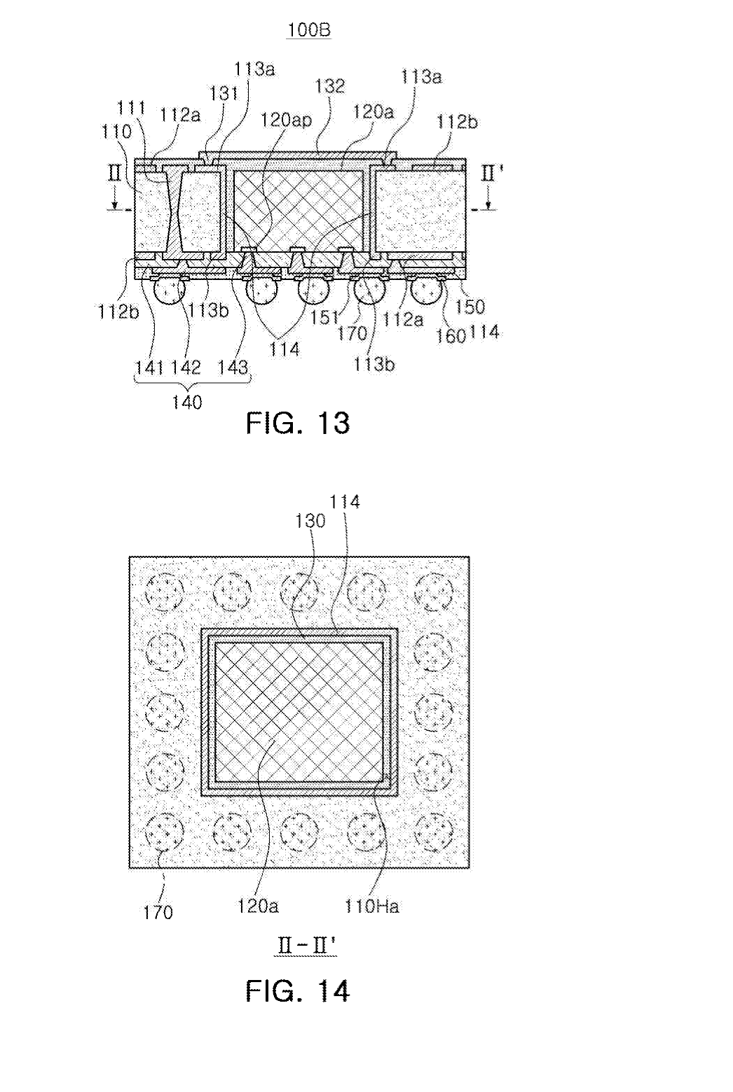

FIG. 13 is a schematic cross-sectional view illustrating another example of a fan-out semiconductor package.

FIG. 14 is a schematic cross-sectional plan view taken along line II-II′ of FIG. 13.

Referring to FIGS. 13 and 14, a fan-out semiconductor package 100B according to another exemplary embodiment includes a frame 110 having a through hole 110Ha, an electronic component 120a disposed in the through hole 110Ha, and having an active surface having an electrode pad 120ap, an inactive surface opposing the active surface, and a side surface connecting the active surface and the inactive surface, and an encapsulant 130 disposed on one sides of the frame 110 and the electronic component 120a, and in a space between the frame 110 and the electronic component 120a in the through hole 110Ha. A first conductive layer 114 is disposed on a sidewall of the through hole 110Ha. In addition, a second conductive layer 113a connected to the first conductive layer 114 is further disposed on one side of the frame 110 surrounding the electronic component 120a. In addition, a line via 131 passing through the encapsulant 130, and connected to the second conductive layer 113a is further disposed in the encapsulant 130 covering the electronic component 120a. In addition, a third conductive layer 132 covering at least the inactive surface of the electronic component 120a, and connected to the line via 131 is further disposed on the encapsulant 130.

The fan-out semiconductor package 100B according to another exemplary embodiment has a single through hole 110Ha, and a single electronic component 120a is disposed in the single through hole 110Ha. For example, the fan-out semiconductor package 100A or 100B according to an exemplary embodiment does not necessarily include a plurality of through holes 110Ha and 110Hb and a plurality of electronic components 120a and 120b.

As set forth above, according to exemplary embodiments, a fan-out semiconductor package capable of addressing various issues due to electromagnetic wave interference and heating and a method of efficiently manufacturing the same may be provided.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a frame having a through hole;
a semiconductor chip disposed in the through hole, and having an active surface having an electrode pad, an inactive surface opposing the active surface, and a side surface connecting the active surface and the inactive surface;
an encapsulant disposed on one sides of the frame and the semiconductor chip, and in a space between the frame and the semiconductor chip in the through hole;
a first conductive layer disposed on a sidewall of the through hole;
a second conductive layer disposed on one side of the frame, and connected to the first conductive layer;
a line via passing through the encapsulant, and connected to the second conductive layer; and
a third conductive layer covering at least the inactive surface of the semiconductor chip on the encapsulant, and connected to the line via.

2. The fan-out semiconductor package of claim 1, wherein the first conductive layer is continuously disposed on the sidewall of the through hole to surround the side surface of the semiconductor chip.

3. The fan-out semiconductor package of claim 2, wherein the second conductive layer is continuously disposed on the one side of the frame to be continuously connected to the first conductive layer.

4. The fan-out semiconductor package of claim 3, wherein the line via continuously passes through the encapsulant to continuously connect the second conductive layer to the third conductive layer and to separate the encapsulant into two discrete portions.

5. The fan-out semiconductor package of claim 1, wherein, the first conductive layer, the second conductive layer, the third conductive layer, and the line via are formed of conductive materials surrounding the inactive surface and the side surface of the semiconductor chip.

6. The fan-out semiconductor package of claim 1, wherein, the first conductive layer, the second conductive layer, the third conductive layer, and the line via completely surround the entire inactive surface and any side surface of the semiconductor chip.

7. The fan-out semiconductor package of claim 1, wherein, the through hole comprises a first through hole and a second through hole, the semiconductor chip is disposed in the first through hole, an electronic component is disposed in the second through hole, and the line via and the third conductive layer are only formed around the semiconductor chip among the semiconductor chip and the electronic component.

8. The fan-out semiconductor package of claim 1, further comprising:
a first wiring pattern and a second wiring pattern disposed on the one side and the other side of the frame, respectively; and
a via passing through the frame, and connecting the first wiring pattern to the second wiring pattern.

9. The fan-out semiconductor package of claim 1, further comprising a redistribution layer disposed on the other sides of the frame and the semiconductor chip, and electrically connected to the semiconductor chip.

10. The fan-out semiconductor package of claim 8, further comprising:
a passivation layer disposed on the redistribution layer, and having an opening exposing at least a portion of a wiring pattern of the redistribution layer;
an under-bump metal layer disposed on the opening, and connected to the wiring pattern; and
a connection terminal disposed on the under-bump metal layer.

11. A method of manufacturing a fan-out semiconductor package comprising:
manufacturing a frame having a through hole;
forming a first conductive layer on a sidewall of the through hole, and forming a second conductive layer on one side of the frame to be connected to the first conductive layer;
disposing, in the through hole, a semiconductor chip having an active surface having an electrode pad, an inactive surface opposing the active surface, and a side surface connecting the active surface and the inactive surface;
forming an encapsulant on one sides of the frame and the semiconductor chip, and in a space between the frame and the semiconductor chip in the through hole;
forming a line via passing through the encapsulant to be connected to the second conductive layer; and
forming a third conductive layer on the encapsulant to be connected to the line via and cover at least the inactive surface of the semiconductor chip.

12. The method of claim 11, wherein the first conductive layer is continuously formed on the sidewall of the through hole to surround the side surface of the semiconductor chip.

13. The method of claim 12, wherein the second conductive layer is continuously formed on the one side of the frame to be continuously connected to the first conductive layer.

14. The method of claim 13, wherein the line via is continuously connected to the second conductive layer, and formed by forming a line via hole continuously passing through the encapsulant to separate the encapsulant into two discrete portions and filling the line via hole with a conductive material.

15. The method of claim 11, wherein the first conductive layer, the second conductive layer, the third conductive layer, and the line via are formed of conductive materials surrounding the inactive surface and the side surface of the semiconductor chip.

16. The method of claim 11, wherein the through hole comprises a first through hole and a second through hole, the semiconductor chip is disposed in the first through hole, an electronic component is disposed in the second through hole, and the line via and the third conductive layer are only formed around the semiconductor chip among the semiconductor chip and the electronic component.
